(19) United States
(12) Patent Application Publication
(10) Pub. No.: US 2024/0040779 A1
(43) Pub. Date: Feb. 1, 2024

(54) ANTIFUSE, APPARATUS, AND METHOD OF FORMING THE SAME

(71) Applicant: MICRON TECHNOLOGY, INC., BOISE, ID (US)

(72) Inventor: SOSHI SATO, Sagamihara (JP)

(73) Assignee: MICRON TECHNOLOGY, INC., BOISE, ID (US)

(21) Appl. No.: 17/816,628

(22) Filed: Aug. 1, 2022

(51) Int. Cl. H01L 27/112

(52) U.S. Cl. CPC H01L 27/11206

(57) ABSTRACT

According to one or more embodiments of the disclosure, an antifuse is provided. The antifuse includes a semiconductor substrate, a dielectric oxide layer on the semiconductor substrate, and a conductive gate layer on the dielectric oxide layer. The dielectric oxide layer includes halogen to facilitate breakdown of the dielectric oxide layer upon application of an antifuse programming voltage.

### BACKGROUND

Memory devices include nonvolatile programmable elements, such as fuses or antifuses, that may be programmed to store information. For example, antifuses (or anti-fuses) of memory devices can be programmed to permanently store information corresponding to one or more addresses of defective memory cells that are remapped to redundant memory cells.

An antifuse has a relatively high resistance in its initial state. The antifuse is programmed by applying a relatively high voltage across the antifuse to create an electrically conductive path. An antifuse can have a structure similar to that of a capacitor, for example, including two conductive electrical terminals separated by a dielectric layer, such as a gate oxide film. To create an electrically conductive path, a relatively high voltage is applied across the terminals, breaking down the interposed dielectric layer and forming a conductive link between the antifuse terminals. Creating a conductive path through an antifuse is referred to as blowing or programming an antifuse.

An antifuse manufactured simultaneously with a transistor has, in general, a similar structure to that of a transistor. For example, a conventional antifuse has a planar interface between an active region and a dielectric layer. When the relatively high voltage is applied to the dielectric layer, electrical stress may be dispersed, and breakdown of the dielectric layer may not be completed. When the breakdown of the dielectric layer is incomplete, a resulting conductive path may have high impedance and may not accurately store the intended information.

Thus, an antifuse with reliable breakdown and programmability is desired.

### BRIEF DESCRIPTION OF THE DRAWINGS

FIG. 1 is a block diagram of a memory device in a plan view according to an embodiment of the disclosure.

FIG. 2 is a schematic diagram of a schematic structure of a semiconductor device in a cross-sectional view according to an embodiment of the disclosure.

FIGS. 3A-3G depict an example of a method of forming a semiconductor device according to an embodiment of the disclosure.

FIGS. 4A and 4B depict an example of a method of forming a semiconductor device according to an embodiment of the disclosure.

FIGS. 5A-5D depict an example of a method of forming a semiconductor device according to the embodiment of the disclosure.

### DETAILED DESCRIPTION

Various embodiments of the disclosure will be described below in detail with reference to the accompanying drawings. The following detailed description refers to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

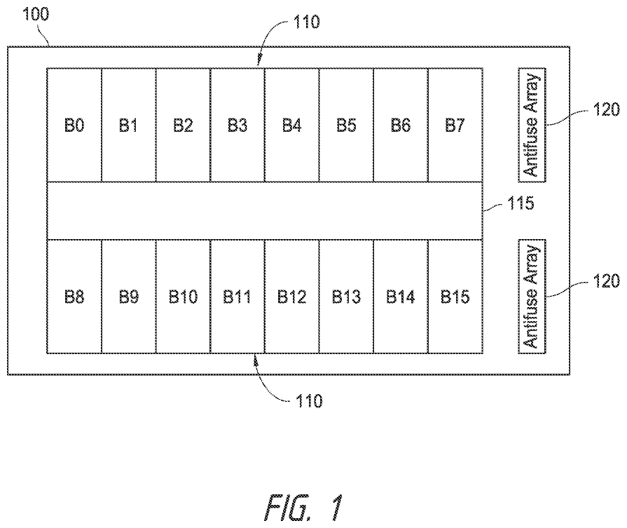

FIG. 1 is a block diagram of a memory device 100 in a plan view according to an embodiment of the disclosure. The memory device 100 includes memory regions 110 that include memory banks BANK0-BANK15 of memory cells. The memory banks may be accessed to read data from and write data to the memory cells. Between the memory regions 110 is a periphery region 115. Various circuits and circuit elements (e.g., transistors) that are used for memory operations are included in the periphery region 115. The memory device 100 further includes antifuse arrays 120. Antifuse arrays 120 include antifuses that may be programmed to store information used by the memory device 100 during operation. For example, the antifuses of the antifuse arrays 120 may be programmed to permanently store address information for defective memory cells, which are remapped to redundant memory to “repair” the defective memory cells. In another example, antifuses of the antifuse arrays 120 may be programmed to permanently store configuration and/or identification information for the memory device 100. Other information may also be stored in the antifuses of the antifuse arrays 120. Antifuses may also be included in additional and/or alternative locations on the memory device 100, for example, in the periphery region 115.

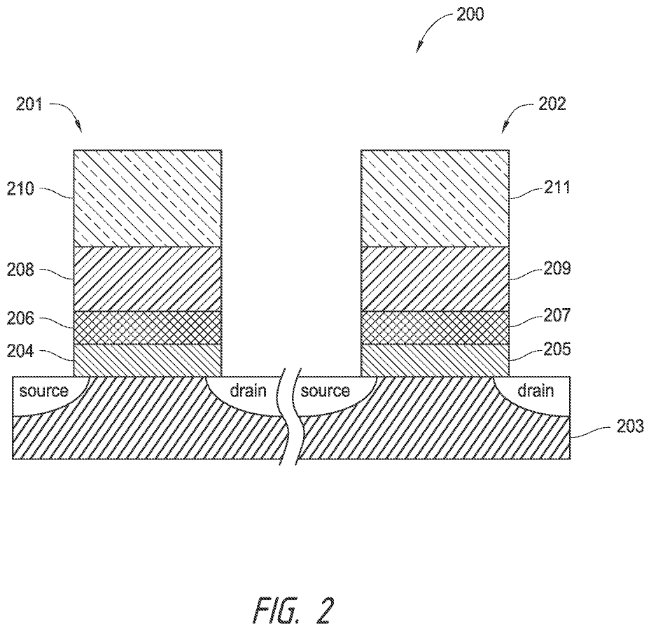

FIG. 2 is a schematic diagram of a schematic structure of a semiconductor device 200 in a cross-sectional view according to an embodiment of the disclosure. In the present embodiment, the semiconductor device 200 is one example of an apparatus that includes a periphery transistor 201 and an antifuse 202 on a semiconductor substrate 203. In the case of the memory device 100 as shown in FIG. 1, for example, the periphery transistor 201 and the antifuse 202 may be provided in regions around or different from the memory regions 100, such as the periphery region 115 and the antifuse arrays 120. The periphery transistor 201 and the antifuse 202 may be manufactured simultaneously on the semiconductor substrate 203 to have a transistor structure. For example, layers and/or films that form the transistor structure or at least a gate stack of the transistor structure, such as an interfacial layer, a dielectric oxide layer, a conductive gate layer, and a gate polysilicon layer, may be formed on the semiconductor substrate 203 during the same processes for both the periphery transistor 201 and the antifuse 202.

The periphery transistor 201 and the antifuse 202 according to the present embodiment includes, respectively, on a surface or a top surface of the semiconductor substrate 203, interfacial layers 204 and 205, dielectric oxide layers 206 and 207, conductive gate layers 208 and 209, and gate polysilicon layers 210 and 211. These layers form at least part of a gate stack of the transistor structure.

The semiconductor substrate 203 may be a silicon (Si) wafer in some embodiments of the disclosure. The semiconductor substrate may be a layer of Si, such as a silicon epitaxial layer, in some embodiments of the disclosure. The semiconductor substrate 203 may include an n-channel region or a p-channel region between a source and a drain for each of the periphery transistor 201 and the antifuse 202.

The interfacial layers 204 and 205 may be insulating films, such as silicon oxide (SiO2) films, silicon nitride (Si3N4) films, silicon oxynitride (SiOxNy) films, or a combination thereof, formed on the top surface of the semiconductor substrate 203. A process of surface nitridation may be applied after formation of the interfacial layers 204 and 205.

The dielectric oxide layers 206 and 207 may be high-k films, such as hafnium oxide (HfO2) films, aluminium monoxide (AlO) films, zirconium dioxide (ZrO2) films, or a combination thereof, deposited on the interfacial layers 204 and 205, respectively. A process of surface nitridation may be applied after deposition of the high-k films. In the case of HfO2, for example, the HfO2 deposition together with the subsequent nitridation improves recoverable bias temperature instability (BTI) of the semiconductor device 200.

In the present embodiment, the dielectric oxide layer 207 of the antifuse 202 may further include halogen, such as chlorine and fluorine, whereas the dielectric oxide layer 206 of the periphery transistor 201 may be halogen free. The inclusion or incorporation of halogen in the dielectric oxide layer 207 of the antifuse 202 may induce defects along an interface between the interfacial layer 205 and the dielectric oxide layer 207. The defects may weaken couplings of a compound used in the dielectric oxide layer 207, such as HfO2, and facilitate breakdown of the dielectric oxide layer 207 and support formation of an electrical path or a conductive link in the antifuse 202 upon application of an antifuse programming voltage. This also enables blowing a fuse or antifuse at either a relatively lower temperature or a relatively higher temperature to further facilitate creating an electrically conductive path through the antifuse, while maintaining the recoverable BTI characteristic. More specifically, for example, in the case of the dielectric oxide layer 207 being the high-k film, the halogen incorporated as an additional material behaves as an impurity or a dopant in the high-k dielectric oxide layer 207 and may cause the high-k oxide to be locally (that is, at the interface between the interfacial layer 205 and the high-k dielectric oxide layer 207) defective around the incorporated halogen. The defects caused by the halogen may be due to: i) its ion radius different from that of oxygen; and ii) its coordination number different from that of oxygen (that is, 2 for oxygen and 1 for halogen). Such defective high-k oxide eases electrical stress at the interface and facilitates complete or substantially complete breakdown of the high-k dielectric oxide layer 207 when a relatively high voltage is applied to blow the antifuse. This increases programmability of the antifuse and achieves a further reliable antifuse.

Referring back to the structure shown in FIG. 2, deposited on top of the dielectric oxide layers 206 and 207 are the conductive gate layers 208 and 209, respectively, which may be metal films, such as Titanium (Ti) films, Tantalum (Ta) films, or Tungsten (W) films, or metal nitride films, such as Titanium nitride (TiN) films, Tantalum nitride (TaN) films, or Tungsten nitride (WN) films. In some embodiments, ternary metal films incorporating, for example, aluminum to metal nitride films, such as Ti—Al—N films, may be used. The gate polysilicon layers 210 and 211, which may be gate polysilicon films, are then deposited on the conductive gate layers 208 and 209, respectively. Subsequently, a thermal process, a gate mask film formation process, and a gate photolithography and patterning process follow to complete the formation of the transistor structure for both the periphery transistor 201 and the antifuse 202 of the semiconductor device 200.

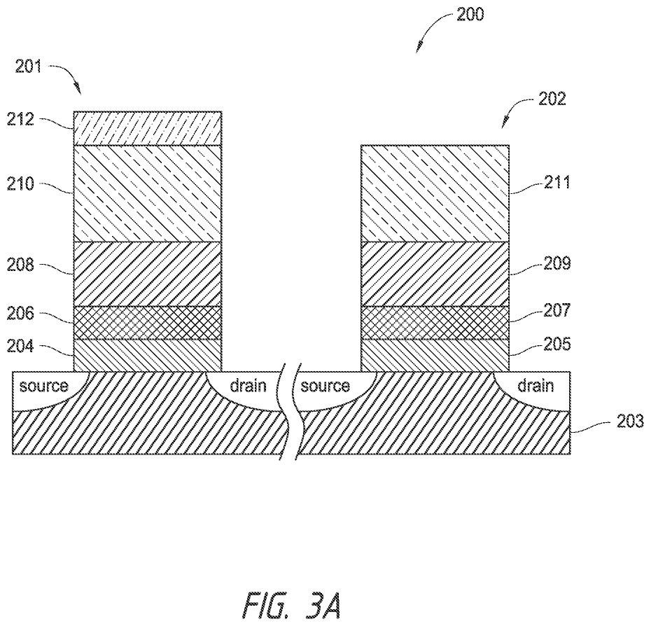

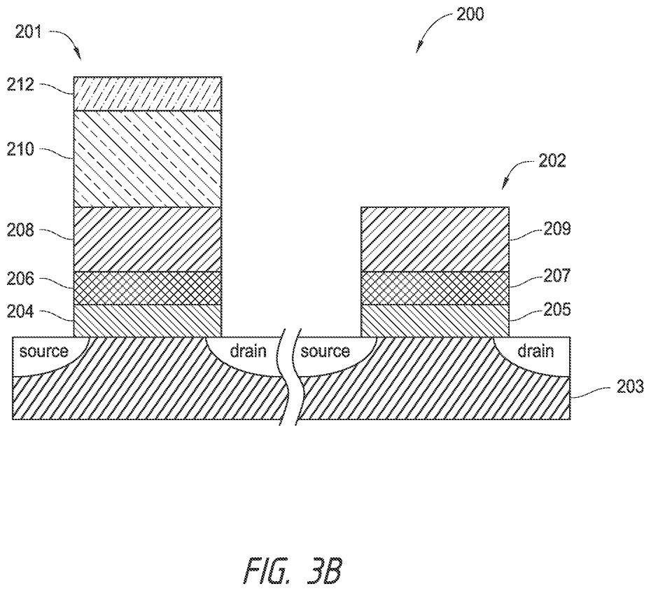

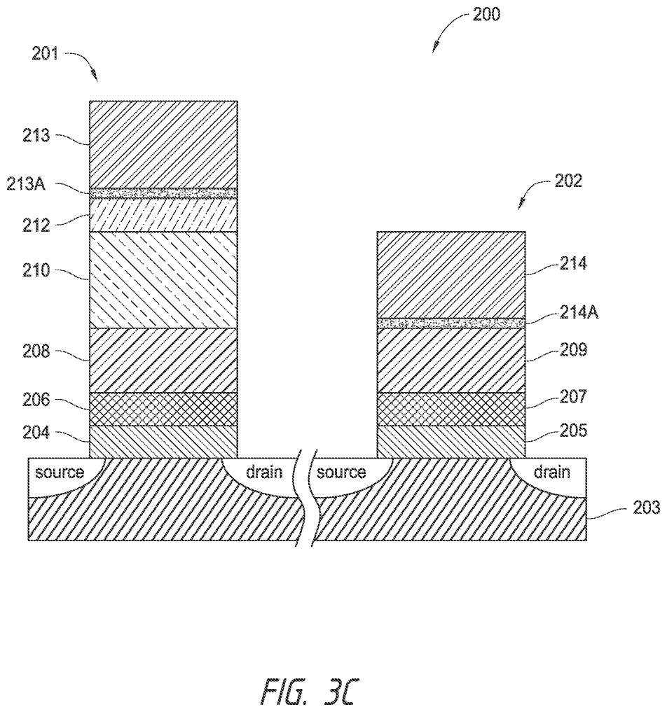

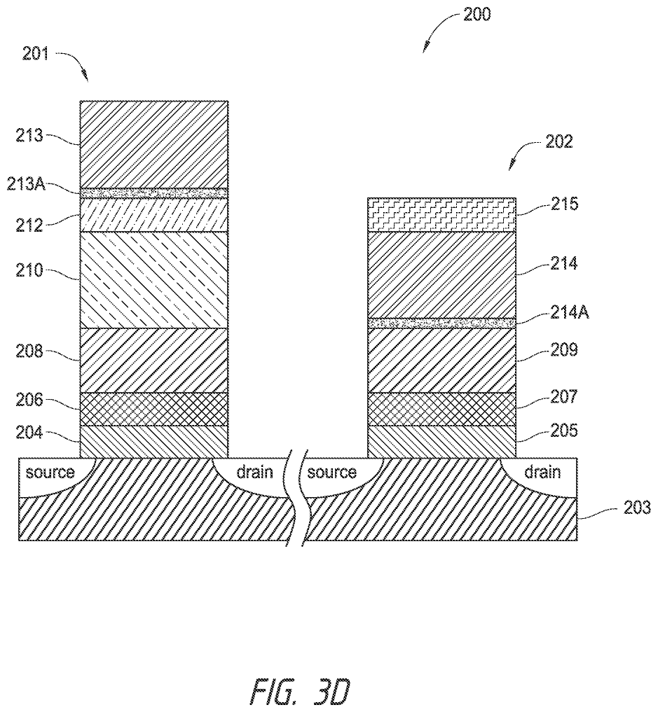

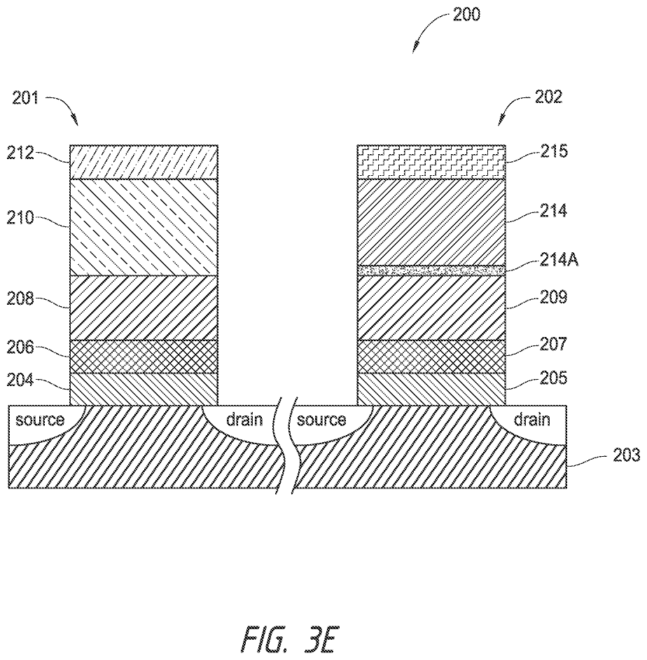

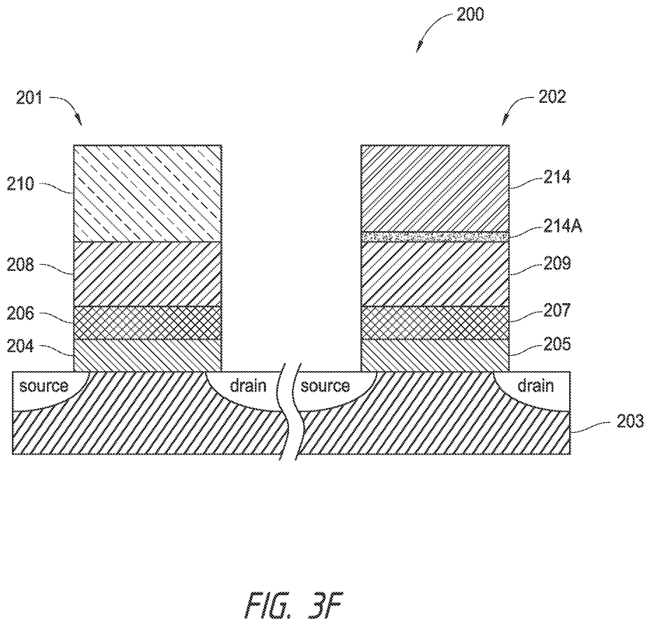

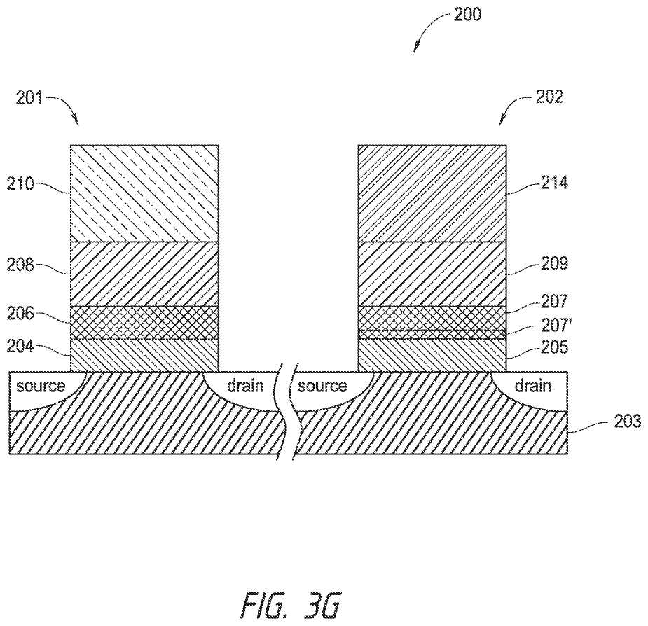

FIGS. 3A-3G depict an example of a method of forming the semiconductor device 200 including the periphery transistor 201 and the antifuse 202 according to some embodiments of the disclosure. More specifically, the depicted method is one example of adding halogen in the dielectric oxide layer 207 of the antifuse 202 as part of the processing of forming the semiconductor device 200.

As a first part of the processing, the interfacial layers 204 and 205, the dielectric oxide layers 206 and 207, the conductive gate layers 208 and 209, and the gate polysilicon layers 210 and 211 are formed on the semiconductor substrate 203. This may be done by, for example, depositing an interfacial layer, a dielectric oxide layer, a conductive gate layer, and a gate polysilicon layer over the substrate 203 (for example, at least in target regions of the substrate 203 where the periphery transistor 201 and the antifuse 202 are to be formed) in that order and etching them to form a gate stack or at least part of a gate stack for both the periphery transistor 201 and the antifuse 202.

As a second part of the processing, as shown in FIG. 3A, a mask 212 is formed on the periphery transistor 201, that is on a top surface of the gate polysilicon layer 210 of the periphery transistor 201. As shown in FIG. 3B, the gate polysilicon layer 211 of the antifuse 202 is then removed, exposing the conductive gate layer 209. The removal of the gate polysilicon layer 211 may be done by, for example, etching or by other appropriate methods.

As shown in FIG. 3C, additional gate polysilicon layers 213 and 214 are deposited on the mask 212 of the periphery transistor 201 and the conductive gate layer 209 of the antifuse 202, respectively. The gate polysilicon layers 213 and 214 may have the same or substantially the same structure and/or the characteristics as the gate polysilicon layers 210 and 211, except that the gate polysilicon layers 213 and 214 include, at a bottom thereof, halogen, forming halogen polysilicon portions (or layers) 213A and 214A, respectively. In the present embodiment, there are no additional layers at least between the gate polysilicon layer 214 and the halogen polysilicon portion 214A and between the halogen polysilicon portion 214A and the conductive gate layer 209 in the antifuse 202. An example of such layers includes but is not limited to an oxidized layer that might prevent the halogen from diffusing toward the dielectric oxide layer 207 at a later process. Similarly, there may be no additional layers, such as oxide layers, at least between the gate polysilicon layer 213 and the halogen polysilicon portion 213A and between the halogen polysilicon portion 213A and the mask 212/the gate polysilicon layer 210 in the periphery transistor 201.

As shown in FIG. 3D, another mask 215 is then formed on the gate polysilicon layer 214 of the antifuse 202. The mask 215 may have the same or substantially the same structure and/or characteristics as the mask 212, or may be different from the mask 212 so long as both mask 212 and 215 can be removed in the following process. As shown in FIGS. 3E and 3F, the gate polysilicon layer 213 including the halogen polysilicon portion 213A is removed from the periphery transistor 201, and both mask 212 and mask 215 are removed.

Subsequently, a thermal process is applied to the entire semiconductor substrate 200 or at least the antifuse 202 on the substrate 203. As shown in FIG. 3G, in the antifuse 202, the halogen in the halogen polysilicon portion 214A at the bottom of the gate polysilicon layer 214 moves through the conductive gate layer 209 and reaches a portion within the dielectric oxide layer 207 adjacent to the interface between the interfacial layer 205 and the dielectric oxide layer 207, such as a bottom portion of the dielectric oxide layer 207 (see the dotted box 207′ in the drawing). Accordingly, the halogen diffuses toward the dielectric oxide layer 207 and is added in the dielectric oxide layer 207 of the antifuse 202. The dielectric oxide layer 206 of the periphery transistor 201 remains halogen free. The halogen 217 added in such a portion within the dielectric oxide layer 207 makes the dielectric oxide or high-k oxide at the interface between the interfacial layer 205 and the dielectric oxide layer 207 defective around the halogen 217 and facilitates breakdown of the dielectric oxide layer 207 to form an electric path or a conductive link in the antifuse 202. Thus, the antifuse 202 may be more easily programmed when an antifuse programming voltage is applied when compared to an antifuse without halogen added to the dielectric oxide layer 207.

According to the present embodiment, the resulting dielectric oxide layer 207 of the antifuse 202 may have the same thickness as that of the halogen-free dielectric oxide layer 206 of the periphery transistor 201. Also, other layers and/or films of the antifuse 202 on the semiconductor substrate 203 may have the same thickness as that of the corresponding layers and/or films of the periphery transistor 201. That is, the processes of adding the halogen to the dielectric oxide layer 207 according to the present embodiment do not affect the layer and/or film thickness, and the size specification of the final transistor structure of each of the periphery transistor 201 and the antifuse 202 does not change regardless of the halogen inclusion.

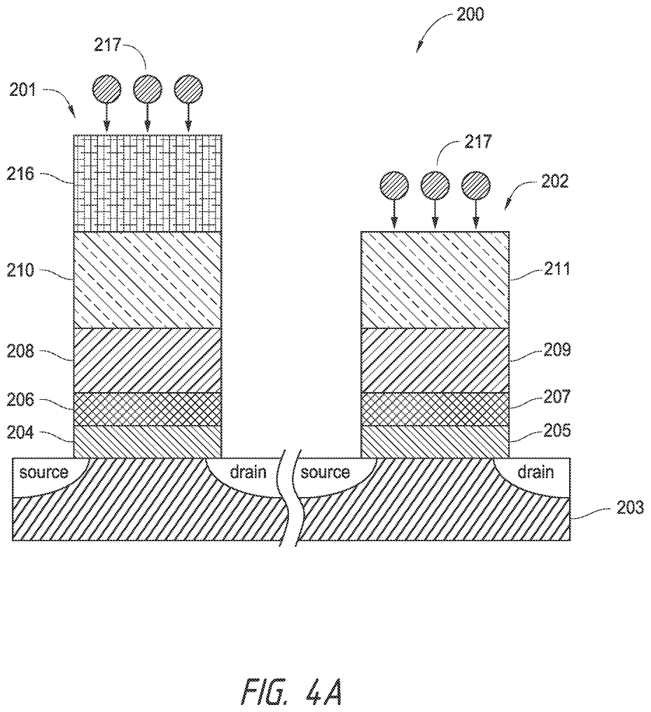

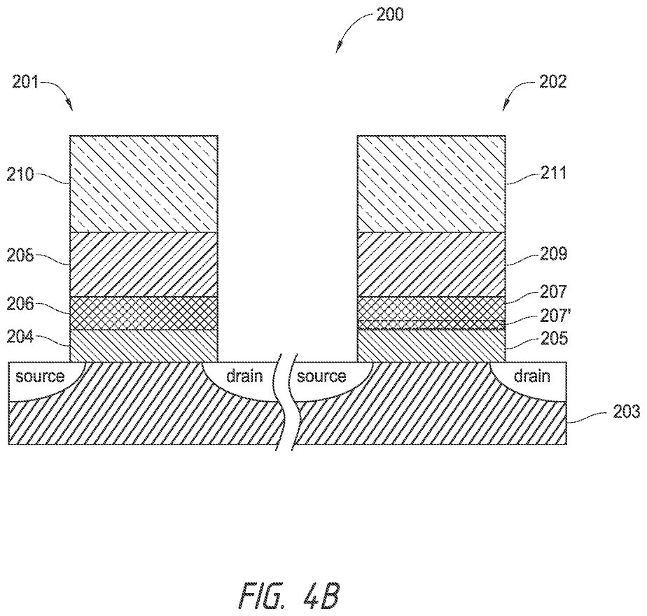

FIGS. 4A and 4B depict another example of adding halogen in the dielectric oxide layer 207 of the antifuse 202 as part of the processing of forming the semiconductor device 200 according to some embodiments of the disclosure.

As shown in FIG. 4A, after the formation of the gate polysilicon layers 210 and 211, a mask 216 is formed on a top surface of the gate polysilicon layer 210 of the periphery transistor 201. Then, halogen (or halogens) 217 are applied onto both exposed surfaces of the periphery transistor 201 and the antifuse 202, which are the top surfaces of the mask 216 and the top surface of the gate polysilicon layer 211. The application of the halogen 217 may be done by ion implantation, plasma treatment, or other appropriate processing. During this process, the mask 216 prevents the halogen 217 from reaching the gate polysilicon layer 210. The mask 216 may thus have such a structure and/or characteristics that halogen 217 does not penetrate to the gate polysilicon layer 210.

As shown in FIG. 4B, the mask 216 is then removed by, for example, etching, and a thermal process is applied to the entire semiconductor substrate 200 or at least the antifuse 202 on the substrate 203. This process causes the halogen 217 to migrate from the gate polysilicon layer 211, through the conductive gate layer 209, and into the dielectric oxide layer 207. Once in the dielectric oxide layer 207, the halogen 217 moves further down to a portion within the dielectric oxide layer 207 adjacent to the interface between the interfacial layer 205 and the dielectric oxide layer 207 (for example, a bottom portion of the dielectric oxide layer 207, as shown by dotted box 207′). Being added in such a portion, the halogen 217 makes the dielectric oxide or high-k oxide at the interface between the interfacial layer 205 and the dielectric oxide layer 207 defective around the halogen 217 and facilitates breakdown of the dielectric oxide layer 207 to form an electric path or a conductive link in the antifuse 202. Hence, when an antifuse programming voltage is applied, the antifuse 202 according to the present embodiment may be more easily programmed than an antifuse without halogen added to the dielectric oxide layer 207. Accordingly, in the present embodiment, the dielectric oxide layer 207 of the antifuse 202 contains the halogen 217, whereas the dielectric oxide layer 206 of the periphery transistor 201 remains halogen free.

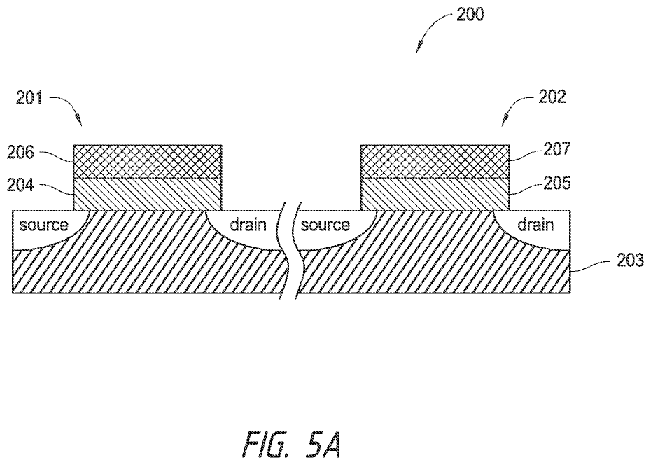

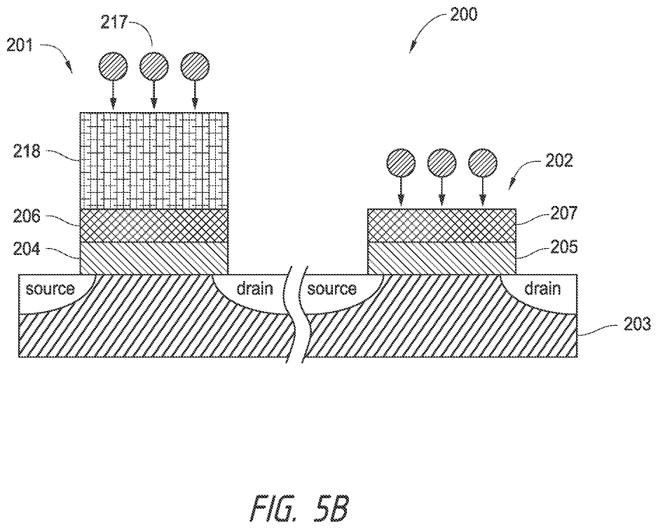

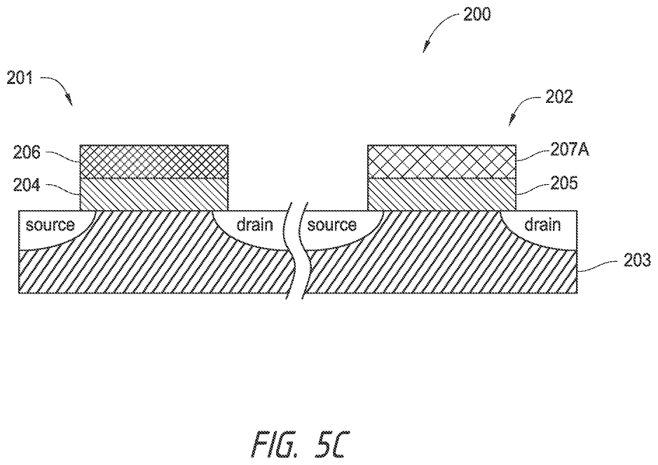

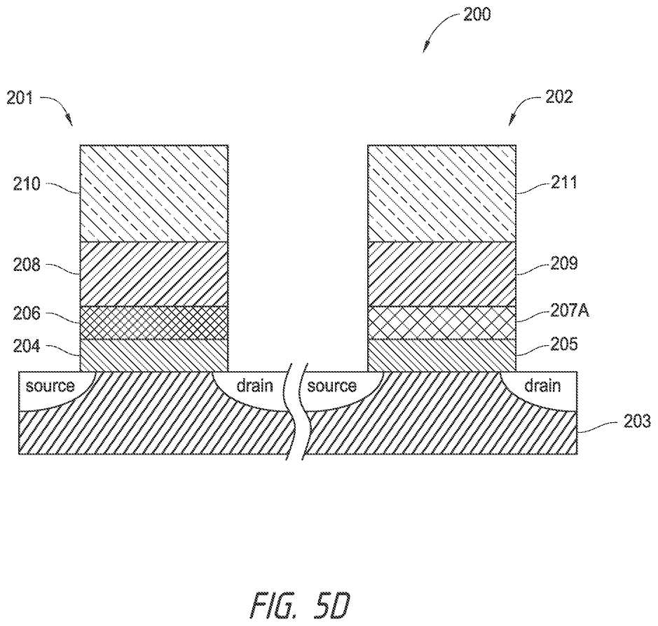

FIGS. 5A-5D depict another example of adding halogen in the dielectric oxide layer 207 of the antifuse 202 as part of the processing of forming the semiconductor device 200 according to some embodiments of the disclosure.

With this example process, as shown in FIGS. 5A and 5B, once the dielectric oxide layers 206 and 207 are formed on the interfacial layers 204 and 205, respectively, a mask 218 (which may have the same or substantially the same structure and/or characteristics as the mask 216 of FIG. 4A) is formed on the dielectric oxide layer 206, and halogen 217 are applied by, for example ion implantation, plasma treatment, or other appropriate processing. During this process, while the mask 218 prevents the halogen 217 from reaching the dielectric oxide layer 206 on the periphery transistor side, the halogen 217 is added to the dielectric oxide layer 207, forming a halogen dielectric oxide layer 207A on the antifuse side as shown in FIG. 5C. Subsequently, as shown in FIG. 5D, after the gate 218 is removed on the periphery transistor side, the conductive gate layers 208 and 209 and gate polysilicon layers 210 and 211 are added to form the gate stack of the transistor structure for both the periphery transistor 201 and the antifuse 202. In the resulting gate stack of the antifuse 202, the halogen 217 in the halogen dielectric oxide layer 207A induces defects along the interface between the interfacial layer 205 and the dielectric oxide layer 207A, weakening couplings of a compound used in the dielectric oxide layer 207A, such as HfO2, and facilitates breakdown of the dielectric oxide layer 207A, forming an electrical path or a conductive link in the antifuse 202. Hence, when an antifuse programming voltage is applied, the antifuse 202 according to the present embodiment may be more easily programmed than an antifuse that does not have a halogen-added dielectric oxide layer.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An antifuse, comprising:
a semiconductor substrate;
a dielectric oxide layer on the semiconductor substrate, the dielectric oxide layer including halogen to facilitate breakdown of the dielectric oxide layer upon application of an antifuse programming voltage; and
a conductive gate layer on the dielectric oxide layer.

2. The antifuse according to claim 1, wherein the dielectric oxide layer is a high-k film.

3. The antifuse according to claim 1, wherein the dielectric oxide layer is a hafnium oxide film.

4. The antifuse according to claim 1, further comprising:
a gate polysilicon layer on the conductive gate layer; and
an interfacial layer between the semiconductor substrate and the dielectric oxide layer.

5. The antifuse according to claim 1, wherein the antifuse is provided in a region different from a memory region on a memory device.

6. An apparatus, comprising:
a first dielectric oxide layer for an antifuse and a second dielectric oxide layer for a periphery transistor on a semiconductor substrate, the first dielectric oxide layer including halogen; and
a first conductive gate layer on the first dielectric oxide layer for the antifuse and a second conductive gate layer on the second dielectric oxide layer for the periphery transistor.

7. The apparatus according to claim 6, wherein the first and second dielectric oxide layers are high-k films.

8. The apparatus according to claim 6, wherein the first and second dielectric oxide layers are hafnium oxide films.

9. The apparatus according to claim 6, further comprising:
a first gate polysilicon layer on the first conductive gate layer for the antifuse and a second gate polysilicon layer on the second conductive gate layer for the periphery transistor; and
a first interfacial layer between the semiconductor substrate and the first dielectric oxide layer for the antifuse and a second interfacial layer between the semiconductor substrate and the second dielectric oxide layer for the periphery transistor.

10. The apparatus according to claim 6, wherein the antifuse and the periphery transistor are provided in first and second regions different from a memory region on a memory device, respectively.

11. A method of forming a semiconductor device, the method comprising:
forming a dielectric oxide layer on a semiconductor substrate for both an antifuse and a periphery transistor; and
adding halogen to the dielectric oxide layer for the antifuse and not to the dielectric oxide layer for the periphery transistor.

12. The method according to claim 11, wherein the halogen is added to a portion within the dielectric oxide layer, the portion being adjacent to an interface between the dielectric oxide layer and a layer underneath the dielectric oxide layer on the semiconductor substrate.

13. The method according to claim 11, further comprising forming a transistor structure for each of the antifuse and the periphery transistor, wherein forming the transistor structure includes:
forming an interfacial layer between the semiconductor substrate and the dielectric oxide layer;
forming a conductive gate layer on the dielectric oxide layer; and
forming a gate polysilicon layer on the conductive gate layer.

14. The method according to claim 11, wherein adding the halogen includes:
forming a gate polysilicon layer above the dielectric oxide layer, the gate polysilicon layer including the halogen; and
applying a thermal process to at least the antifuse to move the halogen in the gate polysilicon layer to the dielectric oxide layer.

15. The method according to claim 11, wherein adding the halogen includes:
forming a gate polysilicon layer above the dielectric oxide layer for both the periphery transistor and the antifuse;
masking the gate polysilicon layer of the periphery transistor;
adding the halogen into the gate polysilicon layer of the antifuse; and
applying a thermal process to at least the antifuse to move the halogen in the gate polysilicon layer to the dielectric oxide layer.

16. The method according to claim 15, wherein adding the halogen into the gate polysilicon layer includes applying ion implantation or plasma treatment.

17. The method according to claim 11, wherein adding the halogen includes:
masking the dielectric oxide layer of the periphery device; and
adding the halogen into the dielectric oxide layer of the antifuse.

18. The method according to claim 17, wherein adding the halogen into the dielectric oxide layer includes applying ion implantation or plasma treatment.

19. The method according to claim 11, wherein the dielectric oxide layer is a high-k film.

20. The method according to claim 11, wherein the dielectric oxide layer is a hafnium oxide film.
